(19) United States
(12) Patent Application Publication
(10) Pub. No.: US 2010/0235696 A1
(43) Pub. Date: Sep. 16, 2010

(54) EMBEDDED TEST SYSTEM AND METHOD

(76) Inventors: Omar Emam, Hertfordshire (GB); Mohammed Yaseen Ali, West Midlands (GB)

Correspondence Address: Pearl Cohen Zedek Latzer, LLP, 1500 Broadway, 12th Floor, New York, NY, 10036, US

(21) Appl. No.: 12/280,754

(22) PCT Filed: Jun. 20, 2008
(86) PCT No.: PCT/GB2008/050469

§ 371 Date: Aug. 26, 2008

(30) Foreign Application Priority Data
Jun. 26, 2007 (GB) 0712373.0

(51) Int. Cl. G01R 31/3177; G06F 11/25

(52) U.S. Cl. 714/727; 714/E11.155

(57) ABSTRACT

An embedded test system is provided where asynchronous communications links are used to pass the boundary scan information by the use of a network router to a boundary scan adapter (54, 60) associated with each component to be tested. This approach enables the system components themselves to facilitate the implementation of a chain-free boundary scan architecture as opposed to a traditional boundary scan bridge approach thus reducing component count and simplifying system design. Thus boundary scan tests can still be performed even after one or more components have been disabled, configured in functional mode or have failed. The same commanding sequence can be applied irrespective of the network topology or the component count since the routing of the boundary scan information is the responsibility of the network routing functionality. This testing method is independent of the underlying functionality of the target hardware or its individual components. The invention also provides for a hybrid solution to adapt boundary scan compatible COTS components so that they can be used within a chainless boundary scan architecture.

Electronic equipment has become increasingly more sophisticated, with digital signal processors being designed to maximize the amount of data handled with minimal volume, mass and power consumption. Most of this processing is being performed within custom ASICs (Application-Specific Integrated Circuits) that are becoming increasingly larger and more complex as the technology evolves. In recent years, ASIC technologies have evolved from a few thousand gates to millions of gates per ASIC. In addition, integration at system level has also increased from a few ASICs to hundreds of ASICs per module, and potentially several thousand ASICs per system. This increased system complexity combined with the need to process and transfer data at very high speeds presents a major challenge for unit as well as system integration, validation and testing. In particular, the challenge is being able to quickly verify that all the electronic components and interconnects are functioning correctly and being able to rapidly identify any faulty components or electrical paths.

The traditional approach of validating equipment by injecting stimuli thereto and verifying the outputs thereof is no longer sufficient or practical. It is now becoming essential that systems are internally tested at subsystem, as well as at module and component/ASIC level. It is no longer possible to perform such comprehensive testing using traditional test methods which rely only on standard external test equipment. The validation of these complex systems now demand that facilities and features to test the system are incorporated as an integral part of the system architecture requiring very little and possibly no external test equipment at all. This approach is referred to as embedded testing.

Such forms of embedded testing are currently being achieved using techniques such as boundary scan (checks interconnections between ASICs), Built-In-Self-Test “BIST” (test programs to test areas which have limited external access e.g. RAM's), signature analysis (comparison of data transferred between ASICs for signal integrity) and incorporation of an advanced test port (to be able to view data through the ASIC chain in real time). While these techniques have proved extremely useful on complex units, the limitations thereof are already becoming evident. In particular, space and aerospace technologies, presents its own unique challenges, in that high levels of system reliability is required to cope with the harsh transport and operating environment combined with the lack of access to repair or replace faulty components. Such reliable systems have to be designed with the ability to diagnose problems and faults remotely and to be able to reconfigure the system by making use of built-in redundant subsystems to recover from faults and to continue to operate as required. Incorporating such test equipment into such conventional systems is not practical or desirable due to the underlying requirement to keep such equipment as simple and as light as possible. Furthermore, the communications links associated with such systems are usually at a premium making reliable permanent connection to ground based test equipment impossible.

It would be desirable to develop and incorporate advanced highly integrated embedded test elements that will enable a built-in test infrastructure to evolve simply as the by-product of the architectural design of the system it is intended to test. This needs to be achieved with minimal hardware overheads. Such an advanced embedded test solution is inherently independent of the configuration architecture of the system it is built to test. This reduces the non-recurrent costs of developing and producing such a system and has the added benefit that this type of embedded test solution can be used to test and validate the system throughout its lifecycle, from leaving the assembly line to and including in-orbit testing in any permitted configuration.

IEEE Std 1149.1 (JTAG) testing standard is a test architecture which has the potential of being adapted for use to implement integrated self-contained embedded test systems of the type described above. It defines a standard architecture for designing boundary-scan test circuitry into digital integrated circuits for the purpose of testing the IC and the interconnections between them when assembled into a system. Boundary scan is currently used in a wide variety of industries ranging from everyday electronic equipment manufacturers, to space satellite applications. IC manufacturers are increasingly ensuring that almost all of their products are IEEE1149.1 compliant to allow boundary scan testing to be performed after assembly. In addition to its original basic functionality, boundary scan currently facilitates many advanced techniques/functionalities. The applications of boundary scan include standard interconnect testing; board level interconnect; mixed signal testing; Built-in-Self test capabilities using IEEE1149.1 where the tests are invoked via IEEE1149.1; In-System Configuration (ISC) where the system code is programmed into the RAM associated with FPGAs, so that on power up, the RAM configures the FPGAs; In-System Programming (ISP) where the system code is loaded into flash which has its data, address and control paths connected to a boundary scan device and embedded testing. The benefits realised from the use of boundary scan are shorter test times, high test coverage, increases diagnostics capability due to the increased access to internal signals and lower capital equipment costs.

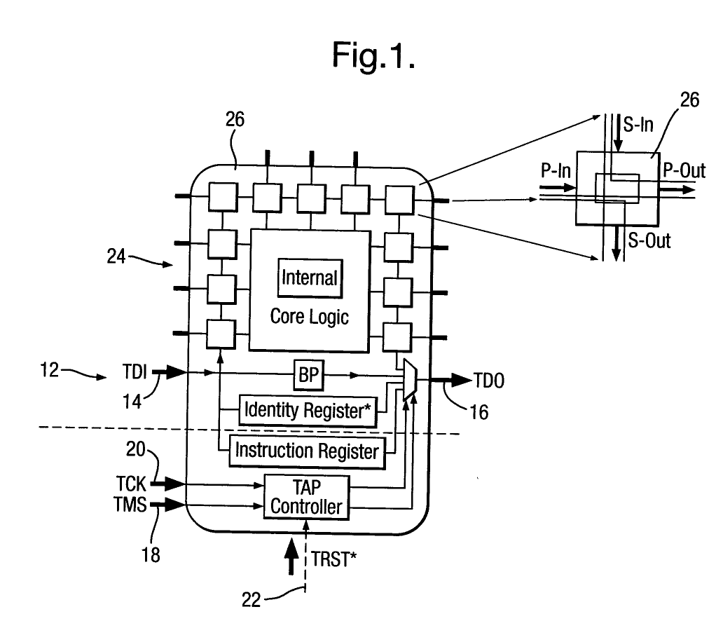

A typical boundary scan cell 10 is illustrated in FIG. 1. All boundary scan compatible devices have a Test Access Port (TAP) 12 with four required pins: Test-Data-Input (TDI) 14, Test-Data-Output (TDO) 16, Test-Mode-Select (TMS) 18 and Test-Clock (TCK) 20 as illustrated in FIG. 1. An optional fifth Asynchronous Test-Reset (TRST) 22 may be provided. At a system level, devices to be tested using boundary scan are connected in a chain referred to as a “scan chain”. In the chain, the TDO 16 of one device is connected to the TDI 14 of the next device in the chain. The TDI 14 of the first device in the chain is typically connected to the external boundary scan equipment via a “scan port”. Similarly the TDO 16 of the last device in the chain is also connected to the “scan port”. The other signals listed above are passed through the “scan port” and are connected in parallel to all devices in the “scan chain”.

Within each device in the chain there is integrated a “boundary register” 24 which is composed of boundary-scan cells 26 arranged as a serial shift register connecting internally between the between the TDI 14 and TDO 16 pins. Under normal operating conditions, these cells 26 are transparent and inactive allowing signals to pass normally. While in Interconnect Test Mode, data shifted into the boundary registers' output cells is driven onto the outputs; and data driven onto the device's inputs is sampled by the input cells and shifted out for comparison to expected results. This simple process of shifting data, updating output cells, and sampling input cells, is the basic algorithm for board-level interconnect fault testing. Multiple boundary-scan compatible devices are linked serially in a daisy chain (TDI 14 of one to TDO 16 of the next), with all devices sharing the same TCK18 and TMS 20. This results in what may be regarded as a single shift register of a fixed length from the system TDI 14 to the system TDO 16.

Typically, a module incorporating boundary scan is designed with only a single “scan chain”. However, there are instances where buffering requirements, redundancy management, the use of different interface logic (e.g. ECL/TTL) and power supply levels and clock domains on the same board, impose the need for multiple “scan chains”, with each chain having its own “scan port”. At system integration, modules that require boundary scan tests to be carried out between them must all have their scan ports connected to the same boundary scan test equipment. This is typically implemented using a multi-drop connection scheme.

As described above, boundary scan techniques require that all the boundary scan-able components are daisy chained. However, such daisy chain architecture has a number of limitations which constrain testing flexibility. Firstly, a faulty ASIC within a daisy chain will prevent testing of the whole chain, especially if the fault is in its boundary scan logic. Furthermore, it is not always possible to partition the chains to match the system architecture (for example, it is desirable to have prime and redundant ASICs on separate chains). This would enable testing under all redundancy configurations without making the design very complex and rigid and would also enable testing under standard operating conditions. In addition, it is not possible to include modular sub-systems in a single boundary scan chain, if these sub-systems are not all available for integration at the same time. The problem is that a missing module will break the scan chain and hence, boundary scan tests cannot be carried out without making some additional test links or dummy modules to bridge the scan chain. This would involve generating additional boundary scan test vectors to cope with these incomplete chains. It is clear that in the particular case of reconfigurable space applications and, in general, for high reliability module redundancy systems, the current daisy chain configuration does not represent a flexible embedded test solution, since the daisy chains must be fixed at the design level.

EP1189070 describes a testing system where boundary scan test vectors are transported from test equipment to the target hardware under test via any asynchronous connection. Transceivers are provided at both the test equipment and the target hardware under test which are configured to arrange that signals arriving from a test access port (TAP) to be transferred through an asynchronous connection so that the received signals can again be synchronised into the mode required by the test access port (TAP). This allows boundary-scan testing to be carried out remotely without a synchronous data transmission connection between the test equipment and the device under test. However, this technique still requires the device under test to incorporate conventional IEEE1149.1 architecture data and hence, the problems associated with the requisite daisy chain configuration described above, are still a limitation. Hence, it is apparent that there is a need for a boundary scan test system that does not require a daisy chain configuration of its components.

It is an object of the present invention to provide an improved test system architecture that would allow boundary scan testing to be transparent and independent of the hardware topology, which is being tested.

It is a further object of the invention to provide a test system architecture that is adapted to handle multiple redundancies, which are generally a requirement for reliable systems such as space hardware, where testing is required with minimum down time.

It is yet a further object of the present invention to provide a chainless boundary scan architecture that can be reconfigured in real time, to suit the particular hardware configuration that has to be tested at that point in time.

From a first aspect, the present invention resides in an embedded test system comprising a plurality of boundary scan compatible devices interconnected by an asynchronous communications network, a test controller module adapted to generate test commands and to receive and analyse scan data from a device under test, a network router to boundary scan adapter associated with each device under test and adapted to transfer test commands and scan data over the asynchronous network and to interpret the test commands and scan data.

The network router to boundary scan adapter preferably comprises one or more input/output interfaces, a network interpreter and assembler device for decoding test commands received on the input/output interfaces and routing or processing received test data or commands; and a test command interpreter and interface adapter for interpreting test commands.

The network router to boundary scan adapter may be integrated within a device under test or may be implemented as a standalone component.

The network router to boundary scan adapter may also include a boundary scan test access port interface adapted to allow connection to an external chain comprising one or more boundary scan compatible devices. Alternatively, the network router to boundary scan adapter may also comprise a gateable router comprising a plurality of test access port interfaces adapted to allow connection to a plurality of external chains, each comprising one or more boundary scan compatible devices. The gateable router may be adapted to allow operation of the plurality of test access port interfaces in parallel and/or to allow one or more of the test access port interfaces to be bypassed.

In a preferred embodiment, the asynchronous communications network comprises a SpaceWire network but alternatively, the asynchronous network comprises any one of the following: Ethernet, RS 232 and 244, IEEE-1355, Blue tooth or WiFi.

Form a second aspect, the invention resides in a method of testing target hardware, the target hardware comprising a plurality of components interconnected by an asynchronous communications network, the method comprising directly transmitting test sequence commands from a remote testing device to each target hardware component to be tested over the asynchronous communications network, interpreting and executing the test sequence directly at each target hardware component and generating test results and transmitting the test results directly from each target hardware component to the remote testing device. In a preferred embodiment, the asynchronous communications network is a SpaceWire network.

The invention advantageously facilitates a chain-free boundary scan architecture allowing the system design to be independent and free of the constraints imposed by the traditional daisy chain type architecture described earlier. Such a chain-free architecture can be achieved by routing the boundary scan test data and signals independently to each component/ASIC without relying on a single pathway or bus. The system's asynchronous communications links are used to pass the boundary scan information when performing embedded test by the use of a Network Router to Boundary Scan adapter associated with each device to be tested. This approach enables the system components themselves to facilitate the implementation of a chain-free boundary scan architecture as opposed to a traditional boundary scan bridge approach thus reducing component count and simplifying system design.

The advantage of the chainless boundary scan architecture described above, is that boundary scan tests can still be performed even after one or more components have been disabled, configured in functional mode or have failed. The same commanding sequence can be applied irrespective of the network topology or the component count since the routing of the boundary scan information is the responsibility of the network routing functionality. This testing method is independent of the underlying functionality of the target hardware or its individual components.

The invention also provides for a hybrid solution to adapt boundary scan compatible COTS components so that they can be used within a chainless boundary scan architecture. This configuration allows a flexible system design to be implemented which can accommodate a combination of traditional boundary scan-able devices others which are equipped with the Space Wire adapted boundary scan adapter modules. This facilitates a hybrid of chainless and traditional boundary scan architectures to be implemented within the same system design.

Embodiments of the invention will now be described with reference to the accompanying drawings in which:

FIG. 1 is a schematic representation of a typical boundary scan cell;

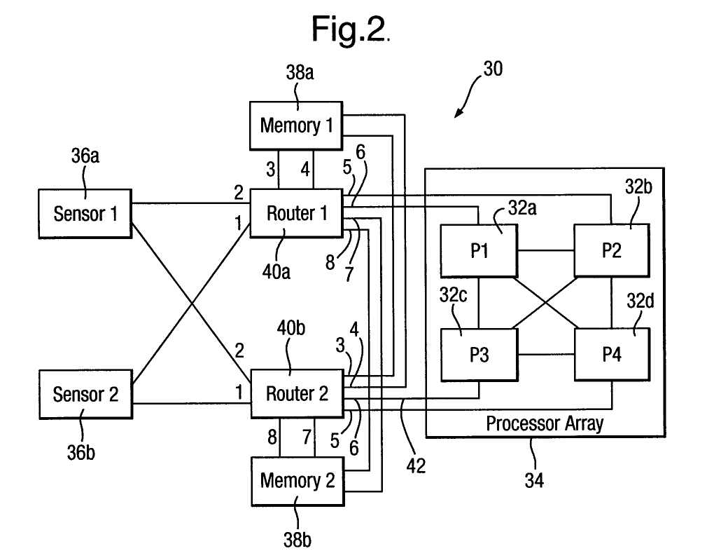

FIG. 2 is a simplified schematic representation of a typical SpaceWire network incorporating four processors;

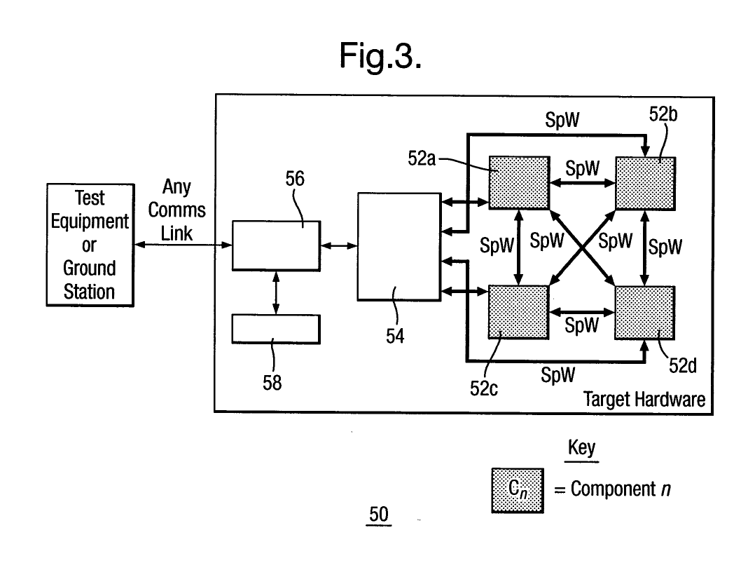

FIG. 3 is a schematic representation of an embodiment of the present invention implemented within a system comprising SpaceWire asynchronous communication links using a chainless boundary scan architecture;

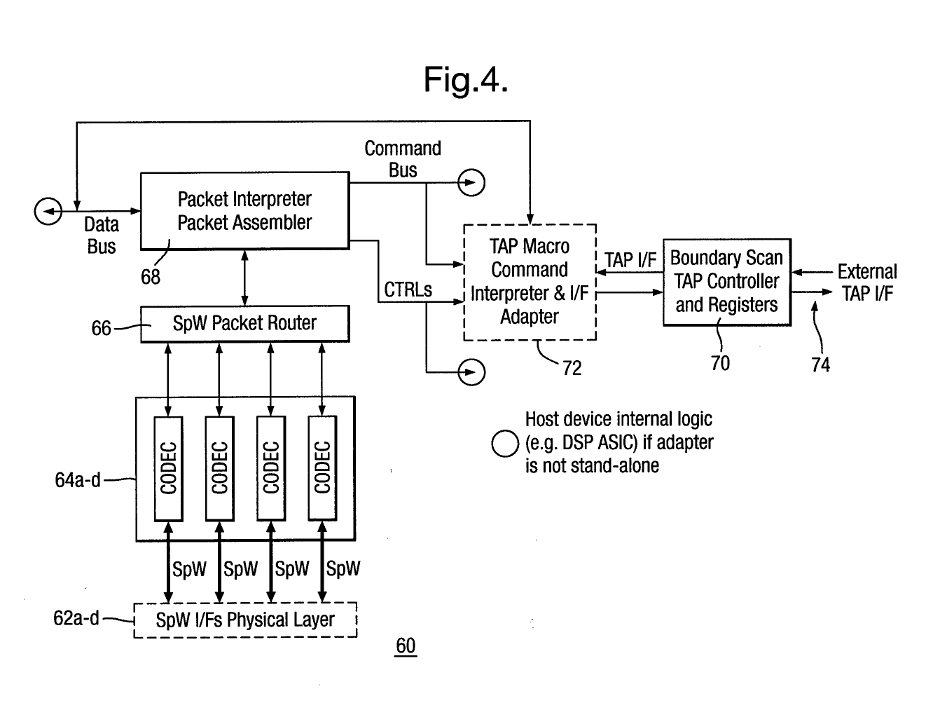

FIG. 4 is a schematic representation of a SpaceWire Router to Boundary Scan adapter module associated with each boundary scan device of FIG. 3, and

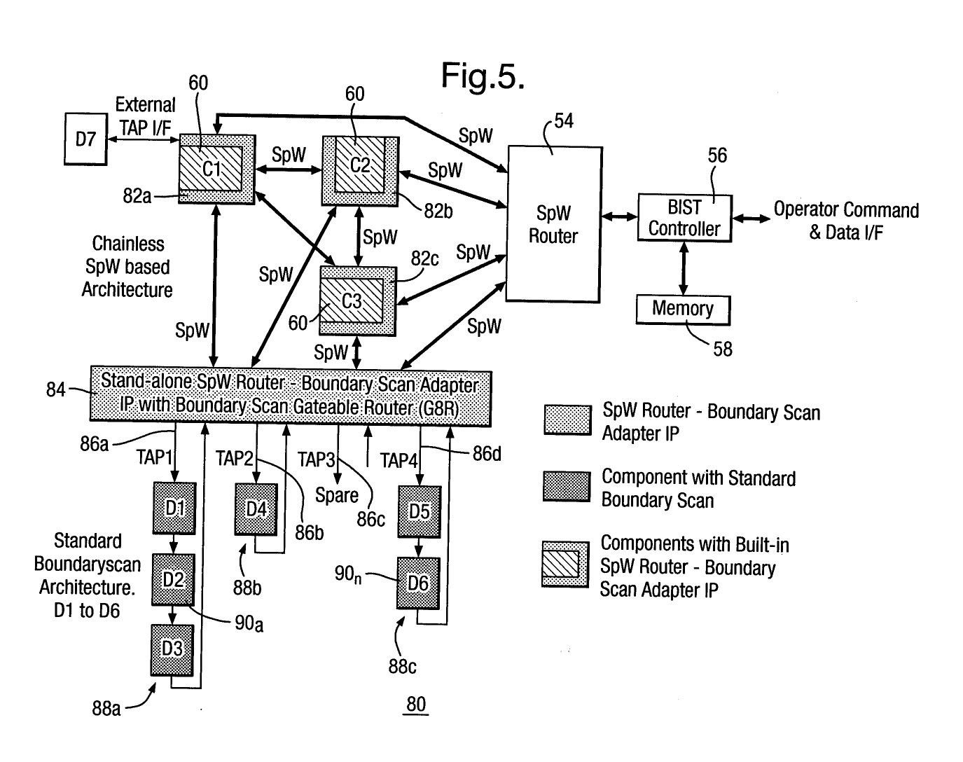

FIG. 5 is a schematic representation of a hybridised chainless and standard boundary scan architecture.

In order to facilitate a better understanding of the invention, the main features of typical SpaceWire network which is used to distribute the boundary scan information in an embodiment of the present invention to be described later will now be briefly summarised. SpaceWire is a standard for high-speed serial data links and networks for use onboard spacecraft, easing the interconnection of sensors, mass-memories, processing units and downlink telemetry sub-systems. A SpaceWire network comprises SpaceWire links, nodes and routers. The nodes are the functional units or components of the space satellite system that uses the onboard communication services of the SpaceWire network. Each node is fitted with one or more SpaceWire interfaces and the nodes are connected together directly using point-to-point SpaceWire links or indirectly via SpaceWire routers, with SpaceWire links making the connections between the node and router.

A typical SpaceWire network 30 is illustrated in FIG. 2. In this example, the processors (P1 to P4) 32a . . . 32d in the processor array 34 are directly connected to one another. The sensors 36a, 36b, memories 38a, 38b and processor array 34 are interconnected via the routers 40a, 40b. Redundancy is provided in this example network by the use of redundant links 42 and a pair of routers 40a, 40b. If data is being sent from Sensor 1, 36a to Memory 1, 38a via Router 1, 40a and the link between the sensor 36a and the router 40a fails, then data can be sent from Sensor 1, 36a to Memory 1, 38a via Router 2, 40b. As described earlier, the SpaceWire network 30 interconnecting the components of the system is designed to enable information to be passed around the network even when at least one SpaceWire link or the component itself has failed.

Information is transferred across a SpaceWire network in distinct packets, each packet comprising a “Destination Address”, a “Cargo” and an “End_of_Packet”. The “Destination Address” is the first part of the packet to be sent and is a list of zero or more data characters that defines the node on the network for which the packet is intended. This list of data characters represents either the identity code of the destination node or the path that the packet will take to get to the destination node. The “Cargo” is the data to be transferred from source to destination. The “End_of_Packet” is used to indicate the end of a packet. A SpaceWire router transfers packets from an input port of the switch where the packet arrives, to a particular output port determined by the packet destination address. A router uses the leading data character of a packet (one of the destination identifier characters) to determine the output port of the router to which the packet is to be routed. If there are two input ports waiting to use a particular output port when the previous packet has finished being sent, then an arbitration mechanism in the output port decides which input port is to be served.

An embodiment of the present invention implemented within a system using SpaceWire asynchronous communication links as the medium to distribute boundary scan information will now be described with reference to FIG. 3. The system 50 consists of four boundary scan compatible integrated circuit devices (C1 to C4) 52a . . . 52d with a number of SpaceWire communications links (SpW1 . . . SpWn) interconnecting each device 52a . . . 52d with the other devices of the system 50. As described with reference to FIG. 2, each device (C1 to C4) 52a . . . 52d may be regarded as a SpaceWire node and incorporates a SpaceWire interface (not shown in FIG. 3) as part of their normal functional requirements. The architecture further includes a SpaceWire router 54 connected to each device (C1 to C4) 52a . . . 52d, a BIST Controller 56 connected to the SpaceWire router 54 and an On-board memory 58. The BIST Controller 56 serves to generate IEEE1149.1 boundary scan commands and data as well as to receive and analyse scan data from the devices 52a . . . 52d under test while the SpaceWire router 54 serves to transfers packets containing the boundary scan commands and scan data from an input port of the switch where the packet arrives, to an output port determined by the packet destination address. This boundary scan information exchange is performed over SpaceWire links SpW1 SpWn between all the components under test 52a 52d and the boundary scan test controller 56. The primary function of the BIST controller 56 is to sequence the tests in an appropriate order and execute the IEEE 1149.1 test vectors for in-orbit level test and diagnosis. The test sequences used by the BIST Controller 56 are stored in the On-Board Memory 58 and are accessed via the BIST controller 56 under the control of the on-board processor (not shown). For System level test, at least one BIST controller 56 is required.

A key feature of the present invention is that there is no requirement that the components to be tested using boundary scan are connected in a “scan chain” with the TDO of one device being connected to the TDI of the next device in the chain. Instead, the system's SpaceWire network SpW . . . Spn is used to pass the boundary scan information when performing embedded test by the use of a SpaceWire Router to Boundary Scan adapter module 60 associated with each device (C1 to C4) 52a 52d shown in FIG. 3.

The SpaceWire Router to Boundary Scan adapter module 60 is illustrated in FIG. 4 and can be implemented either as a stand alone component or as an integral part of each system component 52a . . . 52d to be tested, whether an ASIC, a FPGA or a unit. The adapter module 60 comprises four SpaceWire interfaces 62a . . . 62d which serve as the external input output interfaces and which are part of the normal functional requirements of components within an SpaceWire network and four associated SpaceWire CODECs (coder decoder modules) 64a . . . 64d, a SpaceWire Packet Router 66, a SpaceWire Interpreter and Assembler Module 68, a Boundary Scan TAP Controller module 70, a TAP Command Interpreter and Interface Adapter 72 and an external boundary scan Test Access Port (TAP) 74. It should be understood that while the adapter module 60 illustrated in FIG. 4 comprises four SpaceWire interfaces 62a . . . 62d and four associated CODECs 64a . . . 64d, this is essentially an arbitrary choice and any other appropriate number may be used. However, networking analysis has shown that four serial links is an optimum number of interfaces for a component to enable the most flexible network topologies to be implemented.

The SpaceWire interfaces 62a . . . 62d may be either single ended or LVDS (Low Voltage Differential Signaling), each consisting of 4 signals: Data In, Data Out, Data Strobe In and Data Strobe Out. Each CODEC 64a . . . 64d is connected to an associated interface 62a . . . 62d and handles the first layer of the SpaceWire link protocol. The CODECs 64a . . . 64d also connect to a SpaceWire Packet Router 66 which may either be a virtual address router or a fixed address router. This SpaceWire Packet Router 66 in turn interfaces with a parallel interface (not shown) where data on the SpaceWire network can be presented if it was addressed to it.

The SpaceWire Packet Interpreter and Assembler Module 68 is responsible for decoding commands arriving on the SpaceWire interface 62a . . . 62d and routing or processing the associated data or/and commands appropriately. The levels as defined in the SPW protocol are: (1) Physical level, (2) Signal Level, (3) Character Level, (4) Exchange Level, (5) Packet Level and (6) Network Level. SpaceWire commands are passed within both the signal and character levels. The signal level commands are processed by the CODECs 64a . . . 64d which link directly to the physical level, while the network level commands are defined by the user and require decoding by the Interpreter and Assembler module 68.

The SpaceWire Packet Interpreter and Assembler module 68 connects to the TAP Command Interpreter and Interface Adapter 72 that in turn connects to a TAP controller module 70 and to associated boundary scan data and command registers (not shown). The TAP controller module 70 is responsible for generating all the necessary signals to drive the device's boundary scan circuitry and interfaces and also has an external boundary scan TAP interface 74 which allows it to connect to an external boundary scan chain of one or more boundary scan-able devices as will be described in more detail below.

The TAP Command Interpreter and Interface Adapter 72 can either be in the form of Boundary Scan interface signals as defined by the IEEE1149 standard, or a command/data and control signals interface. In the latter case, the TAP controller module 70 would preferably be synthesised as a state machine which responds directly to the commands, rather than the traditional boundary scan TAP controller where TCK and TMS are used to control its state. The TAP controller 70 would be allocated a specific address or designation so that associated boundary scan commands and data transported on the SpaceWire network can be communicated to it by the SpaceWire Packet Interpreter and Assembler module 68. The external boundary scan Test Access Port (TAP) 74 is of conventional form as described earlier with reference to FIG. 1 comprising the four Test-Data-Input (TDI), Test-Data-Output (TDO), Test-Mode-Select (TMS) and Test-Clock (TCK) pins. Although the TAP Command Interpreter and Interface Adapter 68 is in the form of a standalone module in the embodiment illustrated in FIG. 4, it should be understood that the functionality of this module may be integrated into either the SpaceWire Packet Interpreter and Assembler 68 or the Tap Controller 70.

A typical boundary scan test sequence will now be described. Firstly, the boundary scan test controller 56 primes the system into boundary scan mode by sending the appropriate IEEE1149.1 initialisation commands to all devices 52a . . . 52d in the system 50. Each device 52a . . . 52d transmits an acknowledgement on receiving an initialisation command from the BIST controller 56. In the event that an acknowledgement is not received after a predefined timeout period, the BIST controller 56 will flag an error to the Spacecraft controller and the subsequent set of actions is then defined by the system designers (e.g. automatic re-initialisation or wait for operator intervention).

When all devices 52a . . . 52d are initialised into boundary scan test mode (i.e. an acknowledgment has been received from each device), further IEEE1149.1 boundary scan commands are sent to these devices 52a . . . 52d to enable them to individually receive and shift their specific boundary scan data into the boundary scan register. Once all these registers have been loaded in all the devices 52a . . . 52d and the appropriate acknowledgements received by the BIST controller, further commands are sent to enable the data shifted within each device 52a . . . 52d into their output boundary register cells in order for them to be latched on their I/O's. When all the outputs have been latched and acknowledged to the BIST controller 56, the remaining boundary scan commands are then sent to enable the data driven onto the device's inputs to be sampled and latched by the input boundary scan register cells.

When all the devices 52a . . . 52d have latched their input signals, further IEEE1149.1 commands are sent to enable each to individually shift out their boundary scan over one of the external SpaceWire links to be received by the embedded BIST controller 56 or external test equipment. It should be noted that the ATPG vectors are generated using conventional tools but translation tools which are part of the ground based test equipment, are used to packetise the boundary scan data into SpaceWire packets.

The advantage of the chainless boundary scan architecture described above, is that boundary scan tests can still be performed even after one or more components have been disabled, configured in functional mode or have failed. The same commanding sequence can be applied irrespective of the network topology or the component count since the routing of the boundary scan information is the responsibility of the SpaceWire routing functionality. This testing method is independent of the underlying functionality of the target hardware or its individual components.

Since currently most commercial of the shelf (“COTS”) components which implement boundary scan are not designed for the chainless configuration described above, the invention provides for a hybrid solution to adapt the COTS component so that it can be used within a chainless boundary scan architecture. An example of such a hybrid system 80 is illustrated in FIG. 5 and comprises three devices (C1 to C3) 80a . . . 80c to be tested, each incorporating an inbuilt SpaceWire Router-Boundary Scan Adaptor module 62 as described with reference to FIG. 4. The system 80 further includes a stand-alone modified SpaceWire Router-Boundary Scan adapter module 82 incorporating a Boundary Scan Gateable Router (G8R) 84 that replaces the external Boundary Scan TAP controller logic and interface of the adapter illustrated in FIG. 4. This router is in the form of four external TAP controller interfaces 86a . . . 86d, three of these interfaces 86a, 86b, 86d being connected to three separate boundary scan chains 88a . . . 88c each comprising one or more boundary scan-able devices (D1 . . . Dn) 90a . . . 90n. In the system 80 illustrated, the fourth interface 86c is unused and serves as a spare to which further boundary scan chains 88 may be connected in the future.

The gateable router 84 may be adapted to allow operation of the four interfaces 86a . . . 86d in parallel, to allow daisy chaining in any order, or even the bypassing one or more of the interfaces 86a . . . 86d. It should be appreciated that although the hybrid system 80 illustrated in FIG. 5 incorporates three devices 80a . . . 80c incorporating Space Wire adapted boundary scan blocks (i.e. an integrated SpaceWire Router-Boundary Scan Adaptor module 60) and the gateable router 84 of the standalone adapter 82 is equipped with four external TAP controller interfaces 86a . . . 86d, any appropriate number of either can be used depending on system requirements. This configuration allows a flexible system design to be implemented which can accommodate a combination of traditional boundary scan-able devices (D1 . . . Dn) 90a . . . 90n and others 80a . . . 80c which are equipped with the Space Wire adapted boundary scan adapter modules 60. In essence, the gateable router 84 facilitates a hybrid of chainless and traditional boundary scan architectures to be implemented within the same system design.

It should be understood that although in FIGS. 3 and 4, the SpaceWire router and the SpaceWire to boundary scan adapter module are shown as individual components, the SpaceWire router is in principle a subset of the SpaceWire to boundary scan adapter and the functionality of both may be implemented within a common component which may be a standalone component or an integral part of each device 52a . . . 52d to be tested. It should also be understood that the SpaceWire to boundary scan adapter 60 may be implemented without a SpaceWire router 54. In this case, a single, or preferably dual, (one prime, the other redundant) SpaceWire interface is required with the SpaceWire to boundary scan adapter 60. It should also be appreciated that the use of a Scanbridge is unnecessary within the SpaceWire to boundary scan adapter.

It should also be understood that although the embodiment of invention is described above in the context of boundary scan testing of components of a space satellite system over a SpaceWire network, the invention may be implemented within any asynchronous communications network, such as Ethernet, RS 232 and 244, IEEE-1355, Blue tooth, WiFi . . . etc. Hence, chainless boundary scan has the added advantage in that it allows boundary scan test vectors to be transported via any appropriate communications link to the target hardware and directly executed on a dedicated TAP macro command interpreter similar to that shown in FIG. 4, where the TAP Command Interpreter and Interface Adapter 72 is an integral part of the Tap Controller 70, without having to convert from and to an IEEE1149.1 protocol.

For system level test configuration, it is important to allow the flexibility to test any combination of PCBs and isolating others for diagnostic purposes. Use of the SpaceWire (or any asynchronous link) as the medium for communicating test sequences allows the capability of addressing and selecting a particular PCB, and assigning others to BYPASS mode, to allow more in-depth diagnostics to be performed.

1-13. (canceled)

14. An embedded test system comprising:
a plurality of boundary scan compatible devices interconnected by an asynchronous communications network;
a test controller module adapted to generate test commands and to receive and analyse scan data from a device under test, and a network router to boundary scan adapter associated with each device under test and adapted to transfer test commands and scan data over the asynchronous network and to interpret the test commands and scan data.

15. An embedded test system according to claim 14, wherein the network router to boundary scan adapter comprises:
one or more network input/output interfaces;
a network interpreter and assembler device for decoding test commands received on the input/output interfaces and routing or processing received test data or commands, and a test command interpreter and interface adapter for interpreting test commands.

16. An embedded test system according to claim 15, further comprising a boundary scan controller for generating signals to drive boundary scan circuitry within the device under test.

17. An embedded test system according to claim 14, wherein the network router to boundary scan adapter is integrated within a device under test.

18. An embedded test system according to claim 14, wherein the network router to boundary scan adapter is a stand-alone component.

19. An embedded test system according to claim 14, wherein the network router to boundary scan adapter further comprises a boundary scan test access port interface adapted to allow connection to an external chain comprising one or more boundary scan compatible devices.

20. An embedded test system according to claim 14, wherein the network router to boundary scan adapter further comprises a gateable router comprising a plurality of test access port interfaces adapted to allow connection to a plurality of external chains, each comprising one or more boundary scan compatible devices.

21. An embedded test system according to claim 20, wherein the gateable router is adapted to allow operation of the plurality of test access port interfaces in parallel.

22. An embedded test system according to claim 20, wherein the gateable router is adapted to allow one or more of the test access port interfaces to be bypassed.

23. An embedded test system according to any preceding claim wherein the asynchronous communications network comprises a SpaceWire network.

24. An embedded test system according to any of claims 14 to 22, wherein the asynchronous network comprises any one of the following: Ethernet, RS 232 and 244, IEEE-1355, Blue tooth or WiFi.

25. A method of testing target hardware, the target hardware comprising a plurality of components interconnected by an asynchronous communications network, the method comprising:
directly transmitting test sequence commands from a remote testing device to each target hardware component to be tested over the asynchronous communications network;
interpreting and executing the test sequence directly at each target hardware component and generating test results, and transmitting the test results directly from each target hardware component to the remote testing device.

26. A method according to claim 25, wherein the target hardware is a space satellite system and wherein the asynchronous communications network is a SpaceWire network.
